(19) United States
(12) Patent Application Publication
(10) Pub. No.: US 2006/0138539 A1
(43) Pub. Date: Jun. 29, 2006

(54) Process for treating a semiconductor wafer with a gaseous medium, and semiconductor wafer treated by this process

(75) Inventors: Maximilian Stadler, Haiming (DE); Guenter Schwab, Neuoetting (DE); Christoph Frey, Freiberg (DE); Peter Stallhofer, Burghausen (DE)

Correspondence Address: BROOKS KUSHMAN P.C., 1000 TOWN CENTER, TWENTY-SECOND FLOOR, SOUTHFIELD, MI, 48075, US

(73) Assignee: Siltronic AG, Munich (DE)

(21) Appl. No.: 11/314,102

(22) Filed: Dec. 21, 2005

(30) Foreign Application Priority Data
Dec. 23, 2004 (DE) 10 2004 062 355.4

(51) Int. Cl. H01L 27/12; H01L 21/461

(52) U.S. Cl. 257/347; 438/706

(57) ABSTRACT

A process for treating a semiconductor wafer with a gaseous medium containing hydrogen fluoride and at least one oxidizing agent which oxidizes the surface of the semiconductor wafer, involves flowing the gaseous medium onto the surface of the semiconductor wafer at a relative velocity in the range from 40 mm/s to 300 m/s. Semiconductor wafers and an SOI wafers prepared by the process have a low roughness and metal concentration in the absence of a subsequent polishing step.

### BACKGROUND OF THE INVENTION

1. Field of the Invention

The invention relates to a process for treating a semiconductor wafer with a gaseous medium which contains hydrogen fluoride and an oxidizing agent, and to a semiconductor wafer with low roughness and low metal concentration producible by this process.

2. Background Art

A series of machining steps are carried out as part of the production of semiconductor wafers, in particular silicon wafers, which are used, for example, in the production of electronic components. After the silicon wafer has been cut from a single crystal, it is, for example, lapped and/or ground, in order to produce a surface condition which meets the requirements. To further smooth the surface and to remove the crystal regions which have been damaged by the machining steps (known as damage), the silicon wafer is usually subjected to an etching process, in which the silicon wafer is generally immersed in a liquid medium or has a liquid medium flowing around it.

To remove material by etching in an acidic medium, the silicon must first be oxidized. Only when the silicon is in oxidized form can silicon oxide, generally silicon dioxide (SiO₂), be dissolved by hydrofluoric acid (HF). The oxidation can be effected by means of various chemicals, for example perchloric acid (HClO₄), potassium dichromate (K₂Cr₂O₇) or potassium permanganate (KMnO₄). To achieve smooth and shiny surfaces, however, it is customary to use highly concentrated nitric acid (HNO₃). The oxide which is formed is always removed using hydrofluoric acid, since only this acid is able to dissolve SiO₂.

The following reactions take place during the etching of silicon using a liquid etching medium which contains nitric acid and hydrofluoric acid:

| | | |
|---|---|---|
| Si + 2 HNO₃ | → | SiO₂ + 2 HNO₂ |
| 2 HNO₂ | → | N₂O₃ + H₂O |
| N₂O3 | → | NO₂ + NO |
| SiO₂ + 6 HF | → | H₂SiF₆ + 2 H₂O |
| Si + 2 HNO₃ + 6 HF | → | H₂SiF₆ + 3 H₂O + NO₂ + NO |

Further acids, for example phosphoric acid or acetic acid, are often admixed with the etching medium in order to adjust the viscosity of the etching medium and thereby to alter the properties of the resulting silicon surface. Surfactants are in some cases also added to the etching medium.

The removal of material by etching which is to be established is dependent on various criteria. In general, the removal of material by etching is desired to be sufficient for regions of the crystal lattice which have been damaged during the preceding machining steps. At the same time, it is intended to achieve the lowest possible roughness values and high reflection values, in order to be able to minimize the amount of material removed in a polishing step which generally follows. If the amount of material removed by etching is selected to be sufficiently high, it is possible to achieve very smooth and shiny surfaces.

One drawback is that in the liquid medium with increasing removal of material by etching, the geometry of the silicon wafer which has previously been established by lapping or grinding is altered to an ever increasing extent, which in turn leads to problems during the subsequent polishing process. Geometric errors which were caused prior to polishing can in certain circumstances no longer be corrected by the polishing.

To achieve optimum geometry values, prior to polishing, in the conventional process using liquid etching medium, the removal of material by etching is generally selected in such a way that only damage caused by the machining steps is removed. Depending on the machining process selected, from 10 to 15 μm of material removed by etching on each side of the wafer are sufficient for this purpose. In this case, however, the values which can be achieved for roughness and reflectance of the semiconductor wafer dictate a subsequent polishing step is imperative. This polishing step in turn increases the metal concentration at the surface and in regions of the semiconductor wafer close to the surface.

This stock-removal polishing step takes place at pH >7, preferably in the pH range from 10-11. Under these conditions, predominantly Si—H bonds, which are distinguished by an abundance of electrons, are present at the silicon surface. Cations are attracted by this apparently negatively charged surface, so that positively charged metal ions migrate from the surroundings to the silicon surface in accordance with Coulomb's law and react there according to their chemical potential. Metals which are considered noble in the electrochemical series may even form silicon-metal bonds. Metals which can migrate through the channels of the silicon lattice without using significant energy, on account of their small ion size, release electrons to the conduction band and even at room temperature diffuse unimpeded into the bulk of the silicon wafer. If they find a coordination structure which is ideal for them in energy terms, or a reaction partner which is optimum for them at the empty silicon lattice sites, the entry into the silicon lattice is virtually quantitative. The conditions described are. virtually ideal for copper ions (Cu⁺, Cu²⁺). On account of their small ion size, the channels of the silicon lattice offer no resistance. The dopant boron (B) is an ideal reaction partner, forming Cu—B complexes. The pyramidal coordination field surrounding a silicon lattice site is comparable to copper lattice sites in copper compounds.

U.S. Pat. No. 5,423,944 and U.S. Pat. No. 2004/0020513A1 describe etching processes in which although the etching medium and the oxidizing agent are introduced into the process chamber in gaseous form, they are in the form of an azeotropic mixture with water vapor. The processes are aimed at building up a very thin film of liquid on the surface of the semiconductor wafer. The material removal characteristic is therefore comparable to the removal of material by etching in liquids. Moreover, the semiconductor wafer has to be dried after the etching process. The advantage of the process described in these documents compared to etching in a conventional etching bath filled with liquid is that the influences of convection on the material removal characteristic in the etching process are eliminated.

A further gas-phase etching process is described in U.S. Pat. No. 3,518,132. The process uses a gaseous medium which contains hydrogen fluoride (HF) and nitrogen monoxide (NO) or dinitrogen monoxide (N₂O ). In this case, a layer of corroded material is formed at the silicon surface and has to be removed in a further process step by a liquid alkaline etching medium, such as sodium hydroxide solution. The main drawback of this process is the need for the second process step, since the roughness of the surface increases further during the treatment of the semiconductor wafer in the alkaline etching medium. Therefore, this process can remove damage from the semiconductor wafer but does not allow a smoothing effect.

### SUMMARY OF THE INVENTION

Therefore, an object of the invention was to provide an improved process for etching silicon wafers, which leads to a silicon surface with low roughness and metal concentration, without at the same time having a significantly disadvantageous effect on the geometry of the wafer. These and other objects are achieved by a process for treating a semiconductor wafer with a gaseous medium containing hydrogen fluoride and at least one oxidizing agent which oxidizes the surface of the semiconductor wafer, wherein the gaseous medium flows onto the surface of the semiconductor wafer at a relative velocity in the range from 40 mm/s to 300 m/s.

### DETAILED DESCRIPTION OF THE PREFERRED EMBODIMENT(S)

According to the invention, a gaseous medium, which contains at least hydrogen fluoride (HF) and at least one gas which oxidizes the semiconductor material, preferably ozone, are fed in defined quantities to the surface of the semiconductor wafer. Experiments which have led to the present invention have demonstrated that a gaseous medium without a flow cannot produce significant removal of material by etching, or significant smoothing. Therefore, the crucial factor for the success of the process according to the invention is for the relative velocity between the gaseous medium and the semiconductor wafer to be in the range from 40 mm/s to 300 m/s, preferably in the range from 1 m/s to 100 m/s. Moreover, the gaseous medium is preferably fed to the surface at an angle in the range from 40° to 90°, most preferably at an angle in the range from 75° to 90°. The etching rate is at its maximum if the flow of the gaseous medium strikes the surface of the semiconductor wafer at a right angle, i.e. at an angle of 90°, which is therefore particularly preferred. It is preferable for the flow parameters and the composition of the gaseous medium to be selected in such a way that there is no deposition of a film of liquid on the surface to be treated.

It is preferable for the flow velocity of the gaseous medium to be selected as a function of the geometry of the process chamber in such a way that a non-laminar flow is produced along the surface of the semiconductor wafer. For a given volumetric flow of the gaseous medium, the etching rate is at a maximum if the flow of the gaseous medium strikes the surface of the semiconductor wafer virtually at right angles, i.e. at an angle of 90°. The etching rate can therefore be influenced by the volumetric flow, the angle of incident flow, the mixing ratio of hydrogen fluoride to oxidizing agent and the temperature at which the reaction takes place. It is preferable for the process to be carried out at room temperature and with a molecular mixing ratio of hydrogen fluoride to oxidizing agent in the range from 1:1 to 4:1.

On account of the medium being in the gaseous state, it is possible to achieve very high relative flow velocities between the semiconductor wafer to be treated and the medium which are far higher than the flow velocities achieved when using liquid etching media. Typical flow velocities when using liquid etching media are between 5 mm/s and 40 mm/s. When etching in the gas phase, it is possible to achieve flow velocities of 500 mm/s and above without difficulty. The high flow velocities according to the invention mean that the elevated regions of the wafer surface (i.e. the peaks) are removed first, whereas the lower regions (valleys) are not attacked at all or are only slightly attacked by the gaseous medium. The result of this is that with the aid of the process according to the invention it is possible to produce a very smooth surface with an RMS roughness of less than 70 nm, measured using the Chapman Surface Profiler MP 2000, even when very little material is removed by etching. On account of the very small amount of material removed by etching, the geometry of the semiconductor wafer is scarcely altered, i.e. the geometry which has been produced by preceding planarization steps, such as lapping or grinding, is retained.

It is preferable to dispense with stock removal polishing of the semiconductor wafer after the process according to the invention has been employed. Polishing is generally a multistage process, in which the individual substeps are based on different targets. The individual polishing steps with the exclusion of the final one are collectively referred to by the term “stock removal polishing”, in which in total more than 2 μm of material is removed. Stock removal polishing is required to achieve the quality features of geometry, nanotopography and absence of defects, and to polish away the roughness of unpolished surfaces. The final polishing step is what is known as haze-free polishing (mirror polishing), also known as CMP polishing. It ensures the absence of haze and lowest possible roughness values. The amount of material removed is less than 0.5 μm. This is a relatively short process step. Following the process according to the invention, it is possible to make do without any stock removal polishing, since the process according to the invention already leads to a very smooth surface. Eliminating the stock removal polishing in turn means that the surface of the semiconductor wafer is not recontaminated with metals, since the duration of action of the polishing fluid on the surface of the semiconductor wafer during haze-free polishing is very short. Therefore, the process according to the invention can achieve metal concentrations of less than 1.0×10¹⁰ at/cm² for each of the metals ion, copper, nickel, chromium, zinc and calcium, determined by poly-UTP. Other equivalent measuring methods may of course be used.

For this reason, the present invention also relates to a semiconductor wafer with an RMS roughness of less than 70 nm, measured using the Chapman Surface Profiler MP 2000, and a metal concentration of less than 1.0×10¹⁰ at/cm² for each of the metals iron, copper, nickel, chromium, zinc and calcium, determined by poly-UTP.

The poly-UTP method is a method which is known to those skilled in the art and recognized in the specialist field for simultaneous detection of both bulk metals and surface metals. The detection rate is very high. The method is particularly suitable for detecting, in particular, elements with good diffusion characteristics, such as copper and nickel. A polycrystalline silicon layer which is approximately 1 μm thick is deposited on both sides of a silicon wafer to be analyzed in a quartz tube reactor. As a result, a stress zone, known as damage, is deliberately generated. During a further heat treatment, all the metals migrate virtually quantitatively from their positions in the bulk into the energy-activated damage zone. After cooling, this polycrystalline silicon layer is etched away by wet-chemical means. The metal ions which are then present in the etching solution are determined by means of ICP-MS. The total quantity of each individual metal is given in the unit atoms per square centimeter (at/cm²).

The process according to the invention can also be applied to an SOI wafer. SOI wafers, which are produced for example by a layer transfer process, generally have an RMS roughness of more than 100 nm following the separation step. This roughness is already relatively low compared to the roughness of lapped semiconductor wafers.

On account of the relatively low starting roughness, the process according to the invention can achieve final roughnesses of 0.2 nm (measured using AFM 10×10 μm²) and less even after a short treatment time. Moreover, it is possible to achieve a metal concentration of less than 1.0×10¹⁰ at/cm² for each of the metals iron, copper, nickel, chromium, zinc and calcium, determined by poly-UTP.

Therefore, the invention also relates to an SOI wafer, comprising a silicon layer with a layer thickness of 20 nm or less, an RMS roughness of 0.2 nm or less and a metal concentration of less than 1.0×10¹⁰ at/cm² for each of the metals iron, copper, nickel, chromium, zinc and calcium, determined by poly-UTP. The RMS roughness is measured by AFM (atomic force microscopy), 10×10 μm².

Various possible ways of supplying the gaseous medium to the surface of the semiconductor wafer can be selected within the scope of the invention. By way of example, it is possible to treat the entire surface of the semiconductor wafer by scanning it with a gas nozzle which the gaseous medium flows out of. The distance between the gas nozzle and the surface to be treated is in this case preferably selected in the range from 0.1 mm to 25 mm.

In a preferred embodiment of the invention, a homogeneous treatment of the entire surface is achieved by the entire surface being covered by a gas distributor plate located at a short distance from it. The gas distributor plate is preferably located at a distance of from 0.2 mm to 50 mm above the wafer surface, most preferably at a distance of from 2 mm to 15 mm. The gas distributor plate has suitable gas outlet openings, which determine the flow velocity, the volumetric flow and the angle of incident flow. The gas outlet openings preferably have a diameter of from 0.05 mm to 4 mm, most preferably from 0.1 mm to 2 mm.

It is also possible to provide for a relative movement between semiconductor wafer and gas distributor plate during the etching process. It is in this case possible to rotate the semiconductor wafer or the gas distributor plate at a predetermined speed. It is also possible for the semiconductor wafer and the gas distributor plate to be rotated, in the same or opposite directions, in each case at a predetermined speed. An oscillating movement of the axes of rotation of semiconductor wafer and gas distributor wafer with respect to one another is also possible.

According to a further preferred embodiment of the invention, a homogeneous treatment of the entire surface of the semiconductor wafer can also be achieved with the aid of a slot-shaped gas nozzle, the length of which at least corresponds to the diameter of the semiconductor wafer to be treated. As an alternative to the slot-shaped gas nozzle, it is also possible to use a comb-shaped arrangement of punctiform gas nozzles, in which case the length of the gas nozzle comb once again at least corresponds to the diameter of the semiconductor wafer to be treated. In this embodiment, the treatment of the entire surface is achieved by the fact that the slot-shaped gas nozzle or the gas nozzle comb is moved over the entire surface of the semiconductor wafer at least once, or alternatively the semiconductor wafer is moved past the slot-shaped gas nozzle or the gas nozzle comb. In this case too, the distance between the gas outlet opening or gas outlet openings is preferably from 0.2 to 50 mm, particularly preferably from 2 to 15 mm. In the case of the gas nozzle comb, the gas outlet openings preferably have a diameter of from 0.05 mm to 4 mm, most preferably from 0.1 mm to 2 mm.

It is preferable for the treatment according to the invention to be carried out in a closed process chamber.

According to the invention the gaseous medium contains hydrogen fluoride and at least one oxidizing agent. The oxidizing agent has to be able to oxidize the semiconductor material. For example, when a silicon surface is oxidized, a silicon oxide, preferably silicon dioxide, is formed. This oxide is in turn chemically attacked by hydrogen fluoride, forming hexafluorosilicic acid (H₂SiF₆), silicon tetrafluoride (SiF₄) and water as reaction products, which are discharged by the stream of the gaseous medium. The gaseous medium may also contain further constituents, for example inert carrier gases, such as nitrogen and argon, in order to influence the flow conditions and material removal rates.

It is preferable to use at least one oxidizing agent selected from the group consisting of nitrogen dioxide, ozone and chlorine. If pure chlorine is used, it is necessary to add water vapor in order to oxidize the silicon surface. If a mixture of nitrogen dioxide and chlorine or ozone and chlorine is used, the addition of chlorine serves to use the water which is released in the reaction of hydrogen fluoride with silicon dioxide to further oxidize the silicon surface, and thereby to prevent condensation of the water released in the reaction even at low flow velocities and temperatures. It is particularly preferable to use ozone, on account of its high oxidation potential, the fact that the reaction products do not present any problems, and the ease of providing it by means of ozone generators which are in widespread use in the semiconductor industry.

To produce the gaseous medium, the constituents can be mixed in the desired quantitative ratio. The ratio of hydrogen fluoride to oxidizing agent is typically selected in the range from 1:1 to 4:1. The gaseous medium can be supplied either by the individual components being passed directly into the process chamber or a mixer connected upstream of it or by the gaseous oxidizing agent being passed through a liquid aqueous solution of hydrogen fluoride in a suitable concentration. This can take place, for example, in what is known as a washing bottle or a similar apparatus. As the gaseous oxidizing agent passes through the aqueous solution, it is enriched with water and hydrogen fluoride, so as to form the required gaseous medium.

With the same process parameters and a constant ratio of hydrogen fluoride to oxidizing agent, an increase in the temperature and an increase in the concentrations have a reaction-accelerating effect.

In general, the process according to the invention is used to treat the front surface of the semiconductor wafer. (The front surface is defined as that side of the semiconductor wafer which is intended for the fabrication of electronic components). However, the process may also be applied to the back surface. It can be applied to the front surface and back surface sequentially or simultaneously.

The process according to the invention can advantageously be used as a gas-phase etching process at the following points in the production process for semiconductor wafers:

In the manufacturing sequence sawing—edge rounding—grinding (single-stage or multistage)—etching in liquid—edge polishing—etching in the gas phase according to the invention—stock removal polishing (single-side or double-side)—haze—free polishing (CMP). In this case, the etching in the gas phase serves to reduce the roughness of the semiconductor wafer, with the result that the amount of material which needs to be removed by polishing can be reduced. If multistage grinding processes are used on the wafer surface and wafer edge, the amount of material which needs to be removed to eliminate impurities and surface defects in the crystal structure can be reduced to such an extent that it is possible to dispense with conventional etching in an etching liquid in favor of etching in the gas phase, with a corresponding beneficial effect on the flatness of the semiconductor wafers, which is dominated by the grinding processes.

Another possible manufacturing sequence is sawing—edge rounding—grinding (single-stage or multistage)—etching in liquid—edge polishing—etching in the gas phase in accordance with the invention—stock removal polishing (single-side or double-side)—CMP for polished and epitaxially coated wafers and annealed wafers.

Another possible manufacturing sequence is sawing—edge rounding—grinding (single-stage or multistage)—etching in liquid—etching in the gas phase in accordance with the invention—edge polishing—stock removal polishing.

Another conceivable manufacturing sequence is sawing—edge rounding—grinding (multistage)—etching in the gas phase in accordance with the invention—stock removal polishing (single-side or double-side)—CMP.

A further possible manufacturing sequence is sawing—edge rounding—grinding (multistage)—etching in the gas phase in accordance with the invention—CMP. This manufacturing sequence is preferred since the semiconductor wafers which it produces have a significantly reduced metal concentration, on account of the absence of stock removal polishing. The gas-phase etching process according to the invention and the CMP are sufficient to achieve a very low roughness.

However, it is also conceivable to use a manufacturing sequence of sawing —edge rounding—grinding (single-stage or multistage)—etching in liquid—stock removal polishing (single-side or double-side)—etching in the gas phase in accordance with the invention—CMP.

Another possible manufacturing sequence is sawing—edge rounding—grinding (single-stage or multistage)—etching in liquid—stock removal polishing (single-side or double-side)—CMP—etching in the gas phase in accordance with the invention.

Of course, further steps may be added to the abovementioned manufacturing sequences at suitable points, for example cleaning steps, laser marking, etc.

On account of the possibility of realizing very low material removal rates by suitable selection of flow velocity, volumetric flow, angle of incident flow, mixing ratio of hydrogen fluoride and oxidizing agent and the temperature, and on account of the much greater smoothing effect compared to conventional liquid etching processes, the process according to the invention is in particular also suitable for smoothing and thinning what will subsequently be the active silicon layer of SOI (Silicon on Insulator) wafers.

If the semiconductor wafer is an SOI wafer, the process according to the invention is used to smooth the semiconductor layer (for example a silicon layer) after it has been transferred to the carrier wafer. The manufacturing sequence in this case comprises, for example, the steps of joining donor wafer and carrier wafer—separating the donor wafer along a predefined separating layer—smoothing by etching in the gas phase in accordance with the invention. The etching in the gas phase in accordance with the invention can simultaneously be used to reduce the thickness of the semiconductor layer which is transferred. The process according to the invention can also be applied to SOI wafers which have been produced by means of the SIMOX process. In this case too, it can be used to smooth and if appropriate thin the semiconductor layer.

At the end of the treatment with the gaseous medium in accordance with the invention, the surface of the semiconductor wafer can be conditioned for the subsequent process steps. This preferably takes place immediately after the treatment according to the invention, without removing the semiconductor wafer from the process chamber. To establish a homogeneously hydrophilic surface, first of all the supply of hydrogen fluoride is stopped at the end of the treatment, and a few seconds later the supply of the oxidizing agent is also stopped. If a homogeneously hydrophobic wafer surface is desired, the supply of the oxidizing agent is stopped first, and the supply of hydrogen fluoride is-stopped a few seconds later.

### EXAMPLES

The text which follows summarizes the advantages of the process according to the invention on the basis of Examples and Comparative Examples.

After it had been cut from the single crystal, a single-crystal silicon wafer was cleaned, lapped using FO1200 and cleaned again. The lapped surface had a roughness of Rₐ=0.25 μm. A plurality of pieces of silicon of the same size of approx. 1 cm ×3 cm were prepared from the silicon wafer.

The concentrations of the metals iron, copper, nickel, chromium, zinc and calcium of a second reference wafer produced in the same way were determined by means of poly-UTP. The metal concentrations revealed values of more than 1.0×10¹² at/cm² for each of the abovementioned metals.

The pieces of silicon described were then subjected to a gas phase etching process, in which the gaseous etching medium used was a mixture of oxygen, ozone, hydrogen fluoride and water vapor. The gaseous etching medium was produced as follows:

An ozone generator was supplied with oxygen (99.999%) from a gas cylinder. The power of the generator was selected in such a way that the gas stream which leaves the ozone generator has a concentration of 0.125 g of ozone per liter. The gas stream was passed at room temperature (T=22° C.) through a washing bottle filled with hydrofluoric acid (25% by weight). The gaseous etching medium produced in this way was passed through a Teflon hose into a horizontal PFA tube (80 cm long, diameter=5 cm), the feed and discharge of which can be blocked off on both sides using manually-actuated three-way valves.

### Comparative Example 1

A piece of silicon prepared as described above is placed horizontally into the horizontal PFA tube. The reaction chamber is evacuated with the aid of a water pump jet. Then, the gaseous etching medium described above is introduced into the reaction tube until standard pressure is reached. The reaction tube is then closed using the manually operated valves. At room temperature, the piece of silicon is exposed to the etching medium for five minutes. The removed specimen does not reveal any visual or measurable change in roughness. The metal concentration is greater than 1.0×10¹² at/cm² for iron, copper, nickel, chromium, zinc and calcium, determined by poly-UTP.

### Comparative Example 2

As described in Comparative Example 1, the reaction tube is, five times in succession, evacuated, filled with the gaseous etching medium described above and the piece of silicon is exposed to the stationary etching medium for in each case five minutes at room temperature. The piece of silicon removed after the fifth cycle does not reveal any visual or measurable change in roughness. The metal concentration following the treatment is in the range from 4×10¹¹ at/cm² to 6×10¹¹ at/cm² for iron, copper, nickel, chromium, zinc and calcium, determined in accordance with poly-UTP.

### Comparative Example 3

As described under Comparative Example 2, except that the cycle is carried out 10 times in succession.

### Comparative Example 4

As described under Comparative Example 2, except that the cycle is carried out 15 times in succession.

The result of the Comparative Examples 3 and 4 is identical to that of Comparative Example 2. The piece of silicon does not reveal any visual or measurable change in roughness. The metal concentration remains constant at from 4×10¹¹ at/cm² to 6×10¹¹ at/cm² for iron, copper, nickel, chromium, zinc and calcium, determined by poly-UTP.

### Example 1

A piece of silicon prepared as described above is positioned inclined at an angle of 45° in the horizontal PFA tube. Then, the manually operated valves at the inlet and outlet are opened. The gaseous etching medium described above flows through the reaction tube at a velocity of 50 mm/s. After a reaction time of 30 minutes, a significant smoothing effect was visible at the lower edge of the piece of silicon, at which the gas stream first breaks before then flowing upwards along the inclined plane parallel to the 45° angle; this smoothing effect dropped rapidly along the silicon surface and had completely disappeared after approximately 1.5 cm.

### Example 2

One of the pieces of silicon prepared as described above was placed vertically in the PFA tube. Inside the tube, the gas stream was guided onto the piece of silicon within a thin hose. The outlet opening was narrowed to a diameter of 2 mm. The distance between the outlet opening and the surface of the piece of silicon was approximately 5 mm. The reaction was carried out at room temperature (T=22° C.), and the reaction time was 5 minutes. The calculated flow velocity was 21.3 m/s. After the reaction time had ended, a very smooth circle with a diameter of approximately 5 mm was visually discernable. Material removal amounting to 1.76 μm was determined in the center of the circle. The RMS roughness in the center of the circle was 40 nm. The metal concentrations, determined by the poly-UTP method, were less than 1.0×10¹⁰ at/cm² for each of the metals iron, copper, nickel, chromium, zinc and calcium, determined by poly-UTP.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A process for treating a semiconductor wafer with a gaseous medium, containing hydrogen fluoride and at least one oxidizing agent which oxidizes the surface of the semiconductor wafer, comprising flowing the gaseous medium onto the surface of the semiconductor wafer at a relative velocity in the range from 40 mm/s to 300 m/s.

2. The process of claim 1, wherein the semiconductor wafer is a single-crystal silicon wafer.

3. The process of claim 1, wherein the oxidizing agent is ozone.

4. The process of claim 1, wherein the relative velocity is in the range from 1 m/s to 100 m/s.

5. The process of claim 1, wherein the gaseous medium flows onto the surface of the semiconductor wafer at an angle in the range from 40° to 90° relative to the plane of the wafer surface.

6. The process of claim 5, wherein the angle is in the range from 75° to 90°.

7. The process of claim 1, wherein the gaseous medium is fed to the surface of the semiconductor wafer via a gas distributor plate which is positioned parallel to the semiconductor wafer surface and has a multiplicity of gas outlet openings.

8. The process of claim 7, wherein the semiconductor wafer and the gas distributor plate move relative to each other.

9. The process of claim 1, wherein the gaseous medium is fed to the surface of the semiconductor wafer via a slot-shaped gas nozzle, the length of which at least corresponds to the diameter of the semiconductor wafer, and wherein during the treatment the slot-shaped gas nozzle is moved over the entire surface of the semiconductor wafer at least once or the semiconductor wafer is moved past the slot-shaped gas nozzle at least once.

10. The process of claim 1, wherein the gaseous medium is fed to the surface of the semiconductor wafer via a comb-shaped arrangement of punctiform gas nozzles, the length of the comb-shaped arrangement at least corresponding to the diameter of the semiconductor wafer, and wherein during the treatment the comb-shaped arrangement is moved over the entire surface of the semiconductor wafer at least once or the semiconductor wafer is moved past the comb-shaped arrangement at least once.

11. An etched semiconductor wafer with an RMS roughness of less than 70 nm, and a metal concentration of less than 1.0×10¹⁰ at/cm² for each of the metals iron, copper, nickel, chromium, zinc and calcium, determined by poly-UTP.

12. The semiconductor wafer of claim 11, which comprises single-crystal silicon.

13. An etched SOI wafer, comprising a silicon layer with a layer thickness of 20 nm or less, an RMS roughness of 0.2 nm or less and a metal concentration of less than 1.0×10¹⁰ at/cm² for each of the metals iron, copper, nickel, chromium, zinc and calcium, determined by poly-UTP.

14. An etched semiconductor wafer with an RMS roughness of less than 70 nm, and a metal concentration of less than 1.0×10¹⁰ at/cm² for each of the metals iron, copper, nickel, chromium, zinc and calcium, determined by poly-UTP, and prepared by the process of claim 1.

15. An etched SOI wafer, comprising a silicon layer with a layer thickness of 20 nm or less, an RMS roughness of 0.2 nm or less and a metal concentration of less than 1.0×10¹⁰ at/cm² for each of the metals iron, copper, nickel, chromium, zinc and calcium, determined by poly-UTP, and prepared by the process of claim 1.
